(19) United States
(12) Patent Application Publication
(10) Pub. No.: US 2001/0037823 A1
(43) Pub. Date: Nov. 8, 2001

(54) Process for manufacturing a thin film solar cell sheet with solar cells connected in series

(76) Inventors: Erik Middelman, Arnhem (NL); Jan Winkeler, Zevenaar (NL)

Correspondence Address: Richard P. Fennelly, Akzo Nobel Inc., Intellectual Property Department, 7 Livingstone Avenue, Dobbs Ferry, NY, 10522-3408, US

(21) Appl. No.: 09/740,773

(22) Filed: Dec. 19, 2000

(30) Foreign Application Priority Data
Dec. 21, 1999 (NL) 1013900

(51) Int. Cl. H01L 21/00; H01L 25/00; H01L 31/00

(52) U.S. Cl. 136/251; 136/244; 136/256; 438/64; 438/66

(57) ABSTRACT

The invention pertains to a process for manufacturing a thin film solar cell sheet provided with a plurality of solar cells connected in series which comprises the following steps:

a. providing a temporary substrate;

b. optionally providing a diffusion barrier layer;

c. applying a transparent conductive oxide (TCO);

d. applying a photovoltaic (PV) layer onto the TCO;

e. providing a groove (1) through the PV layer and, if so desired, through the TCO;

f. applying a back electrode onto the PV layer and in groove (1) and, when groove (1) has been provided through the TCO, if necessary providing a groove (2) in the back electrode inside groove (1) down to the temporary substrate in such a way that on one side of groove (2) the TCO and the back electrode are not interconnected, and when groove (1) has not been provided through the TCO, providing a groove (2a) through the back electrode down to the PV layer next to groove (1);

g. applying a non-conductive material in grooves (1) and (2) or (2a), optionally combined with or followed by the application of a permanent substrate;

h. removing the temporary substrate;

i. providing a groove (3) from the TCO side through the TCO and, if so desired, through the PV layer outside groove (1) on the side of groove (1) opposite from groove (2) or (2a);

j. when groove (1) has been provided through the TCO, establishing a conductive connection between the TCO on the side of groove (2) where the TCO and the back electrode are not interconnected and the back electrode on the opposite side of groove (2);

k. applying an insulating material in groove (3) and, if so desired, simultaneously or successively over the top of the thin film solar cell sheet.

This application claims priority from Netherlands Patent Application No. 1013900, filed on Dec. 21, 1999.

The invention pertains to a process for manufacturing a thin film solar cell sheet with solar cells connected in series, more particularly, to a process for manufacturing a thin film solar cell sheet with solar cells connected in series which is suitable for use in the manufacture of flexible thin film solar cell sheets based on a temporary substrate.

Thin film solar cell sheets as a rule comprise a carrier and a photovoltaic layer composed of a semiconductor material provided between a front electrode (at the front of the thin film) and a back electrode (on the carrier side of the thin film). The front electrode is transparent, enabling incident light to reach the semiconductor material, where the incident radiation is converted into electric energy. In this way light can be used to generate electric power, which offers an interesting alternative to, say, fossil fuels or nuclear power.

The maximum voltage of a solar cell is determined by the intensity of the incident light and by the composition of the cell, more particularly, by the nature of the semiconductor material. When the surface area of the solar cell is increased, more power is generated, but the voltage remains the same. In order to increase the voltage, a thin film solar cell sheet is often divided up into a number of different cells, which are then connected in series. This is usually done by providing grooves in the thin film, e.g., using a laser or by means of etching, and establishing a conductive contact between the front electrode of one cell and the back electrode of the other. When a thin film solar cell sheet is employed, the individual cells are held together by the carrier.

A comparatively recent trend in the manufacture of thin film solar cell sheets is the use of a temporary substrate. Thus EP 0 218 193 discloses a process for manufacturing a thin film solar cell sheet using an endless band as a surrogate substrate. On the endless band are deposited, successively, a back electrode and a photovoltaic layer (PV layer), after which grooves are provided in the PV layer. Next, a layer of a transparent conductive oxide (TCO) is applied, which is provided with grooves in its turn. A support material is then applied, after which the whole is separated from the surrogate substrate.

There are a number of drawbacks to this system. First of all, the TCO is applied on top of the PV layer. This means that during the application of the TCO the temperature selected has to be such that there is no damage to the PV layer. Consequently, it is not possible to employ such attractive materials as F-doped tin oxide (SnO₂) as TCO, since it is preferably applied at above 400° C., a temperature the PV layer is not resistant to. Another drawback to this system is that the carrier which is applied onto the TCO layer has to be of such thickness and strength as will enable it to keep the thin film solar cell sheet together after the removal of the temporary substrate. Because said carrier layer is situated on the TCO side of the thin film solar cell sheet, i.e. the side where incident light has to be absorbed, the carrier also has to be sufficiently transparent. Thus very high demands are made as regards the nature of the carrier.

Both these problems are obviated in WO 98/13882. This publication discloses a process for manufacturing thin film solar cell sheets in which, successively, a TCO layer, a photovoltaic layer, a back electrode, and a carrier are applied onto a temporary substrate, followed by removal of the temporary substrate. In this publication various ways of effecting connection in series are described. For instance, after the application of each layer grooves can be provided in the just applied layer by laser scribing or by etching. Also mentioned is the possibility of establishing a series connection by providing grooves on either side of the thin film solar cell sheet, but no further details on this are given.

The present invention provides a process for manufacturing a thin film solar cell sheet with solar cells connected in series in which the opportunity to provide grooves on either side of the thin film solar cell sheet, which is made possible by the use of the temporary substrate, is exploited.

The process according to the invention comprises the following steps:

a. providing a temporary substrate;

b. optionally providing a diffusion barrier layer (DB layer);

c. applying a transparent conductive oxide (TCO);

d. applying a photovoltaic (PV) layer onto the TCO;

e. providing a groove (1) through the PV layer and, if so desired, through or partly through the TCO;

f. applying a back electrode onto the PV layer and in groove (1) and, when groove (1) has been provided through the TCO, if necessary providing a groove (2) in the back electrode inside groove (1) down to the temporary substrate in such a way that on one side of groove (2) the TCO and the back electrode are not interconnected, and when groove (1) has not been provided through the TCO, providing a groove (2a) through the back electrode down to the PV layer next to groove (1);

g. applying a non-conductive material in grooves (1) and (2) or (2a), optionally combined with or followed by the application of a permanent substrate;

h. removing the temporary substrate;

i. providing a groove (3) from the TCO side through the TCO and, if so desired, through or partly through the PV layer outside groove (1) on the side of groove (1) opposite from groove (2) or (2a);

j. when groove (1) has been provided through the TCO, establishing a conductive connection between the TCO on the side of groove (2) where the TCO and the back electrode are not interconnected and the back electrode on the opposite side of groove (2);

k. applying an insulating material in groove (3) and, if so desired, simultaneously or successively over the top of the thin film solar cell sheet.

The process according to the invention comprises three specific embodiments.

The first embodiment is the simplest one. In it groove 1 is not provided through the TCO in step e, while in step f next to groove (1) a groove (2a) is provided through the back electrode down to the PV layer. This process thus comprises the following steps:

a. providing a temporary substrate;

b. optionally providing a diffusion barrier layer;

c. applying a transparent conductive oxide (TCO);

d. applying a photovoltaic (PV) layer onto the TCO;

e. providing a groove (1) through the PV layer down to the TCO;

f. applying a back electrode onto the PV layer and in groove (1);

g. providing a groove (2a) through the back electrode down to or, if so desired, through the PV layer, but not completely through the TCO layer, next to groove (1);

h. applying a non-conductive material in grooves (1) and (2a), optionally combined with or followed by the application of a permanent carrier;

i. removing the temporary substrate;

j. providing a groove (3) through the TCO and, if so desired, through the PV layer on the side of groove (1) opposite from groove (2a);

k. applying an insulating material in groove (3) and, if so desired, simultaneously or successively over the top of the thin film solar cell sheet.

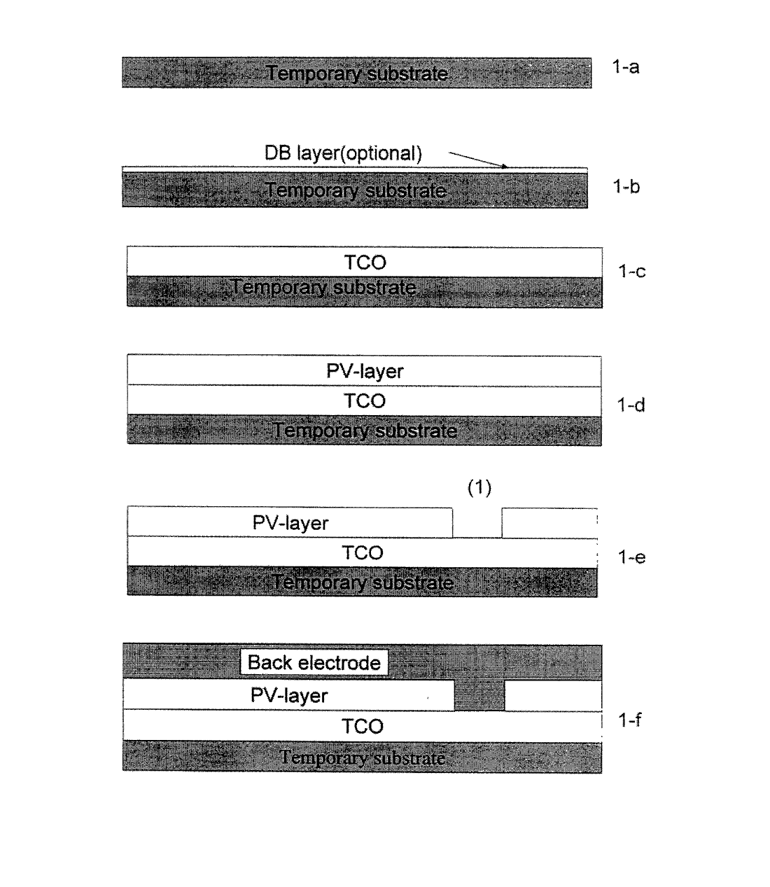

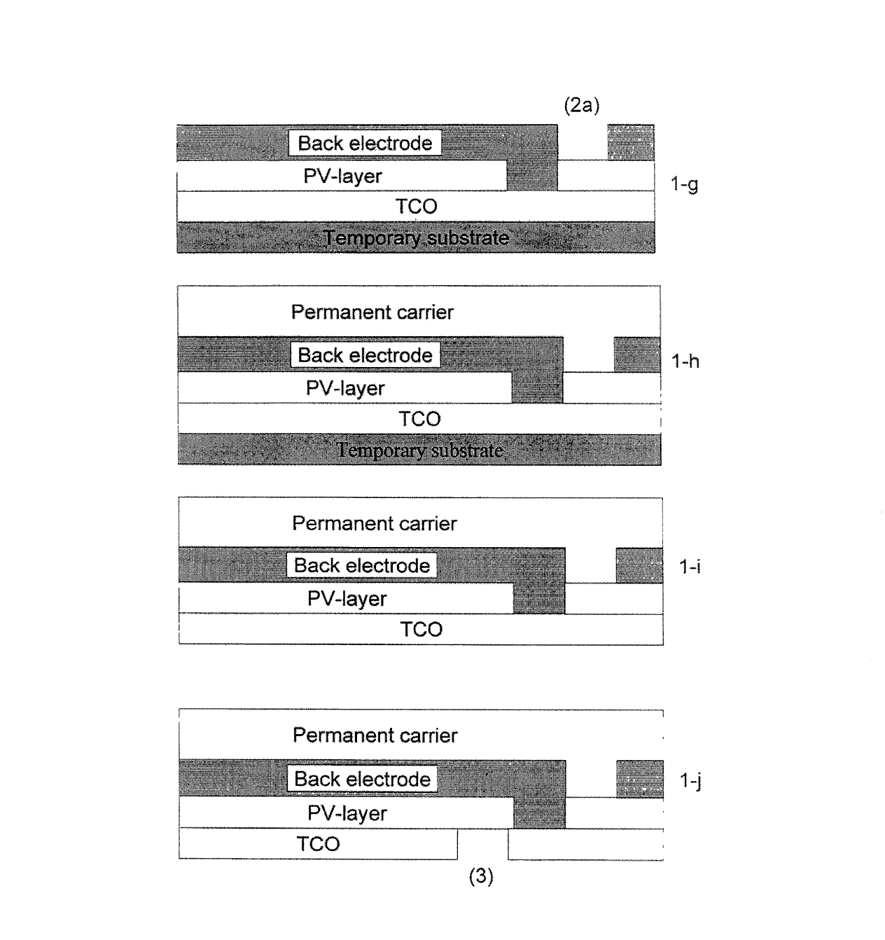

This process is further illustrated in FIG. 1, with FIGS. 1-a to 1-k corresponding to steps a-k as described above.

The process according to the embodiment specified above is characterized by its simplicity. A more sophisticated embodiment of the process according to the invention is the one in which in step e groove (1) is provided through the TCO down to the back electrode, in step f, if necessary, a groove (2) is provided in the back electrode inside groove (1) down to the temporary substrate in such a way that on one side of groove (2) the TCO and the back electrode are not interconnected, and in step j a conductive connection is established between the TCO on the side of groove (2) where the TCO and the back electrode are not interconnected and the back electrode on the opposite side of groove (2). This process thus comprises the following steps:

a. providing a temporary substrate;

b. optionally providing a diffusion barrier layer;

c. applying a transparent conductive oxide (TCO);

d. applying a photovoltaic (PV) layer onto the TCO;

e. providing a groove (1) through the TCO and the PV layer;

f. applying a back electrode onto the PV layer and inside groove (1) and, if necessary, providing a groove (2) in the back electrode inside groove (1) down to the temporary substrate in such a way that on one side of groove (2) the TCO and the back electrode are not interconnected;

g. applying a non-conductive material in grooves (1) and (2), optionally combined with or followed by the application of a permanent carrier;

h. removing the temporary substrate;

i. providing a groove (3) from the TCO side through the TCO and, if so desired, through the PV layer down to the back electrode, with the groove being provided outside groove (1) on the side of the groove where the TCO and the back electrode are interconnected;

j. establishing a conductive connection between the TCO on the side of the groove (2) where the TCO and the back electrode are not interconnected and the back electrode on the opposite side of groove (2);

k. applying an insulating material in groove (3) and, if so desired, simultaneously or successively over the top of the thin film solar cell sheet.

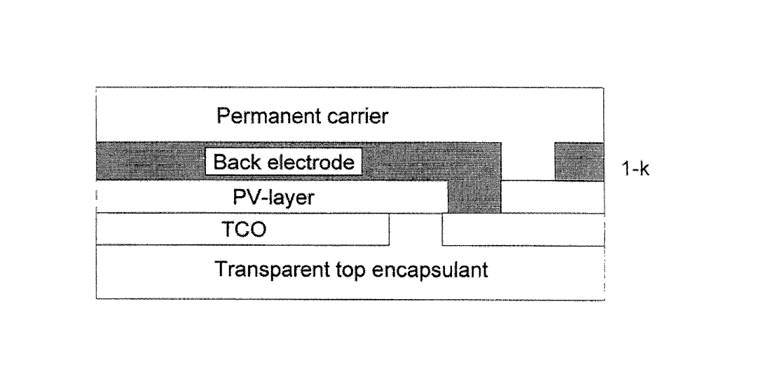

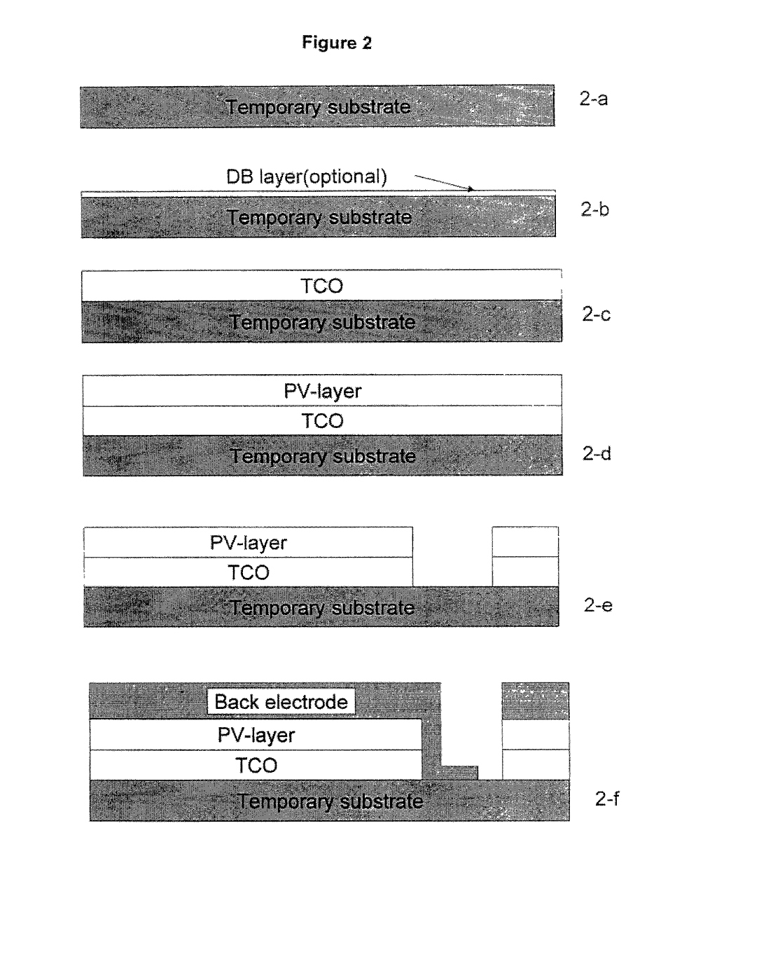

This process is further illustrated in FIG. 2, with FIGS. 2-a through 2-k corresponding to steps a-k as described above.

The crux of groove (2) in the embodiment illustrated in FIG. 2 is that one side of groove (1) is covered with back electrode down to the bottom of the groove, while the other side of groove (1) remains free of back electrode. At least a part of the bottom of groove (1) has to remain free of back electrode in order to prevent any conductive contact between the two sides of the groove. This conductive contact is only made when a conductive connection is established in step 2-j.

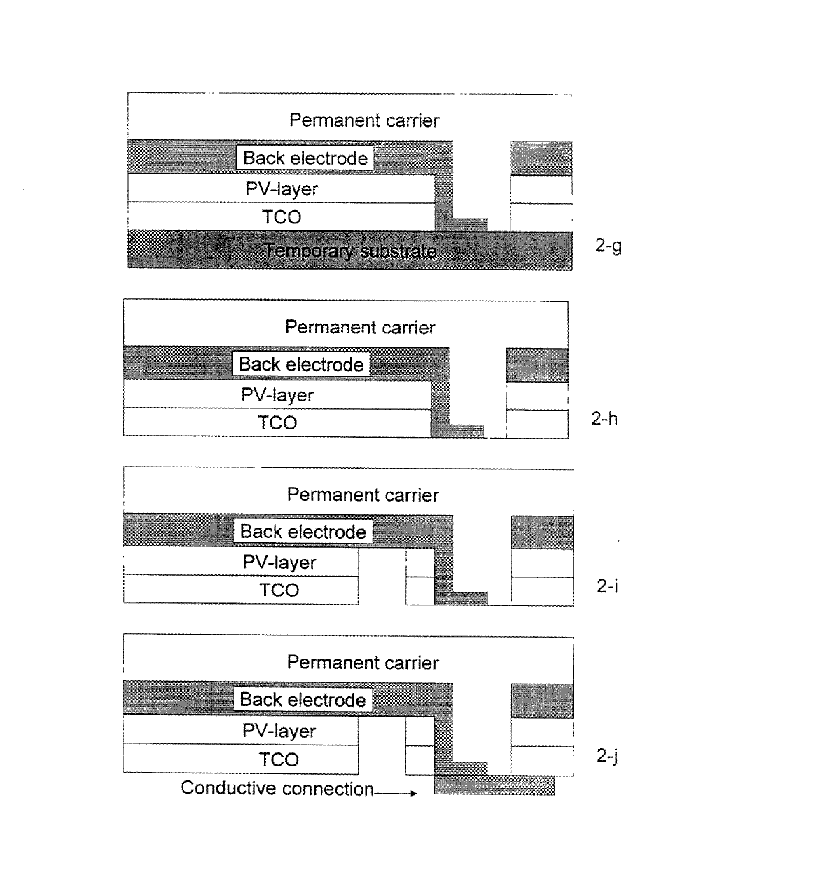

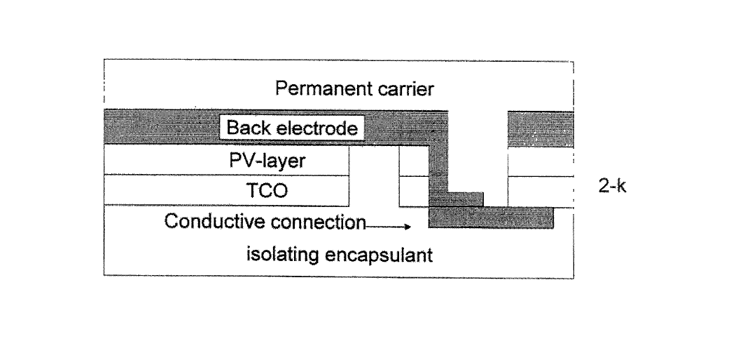

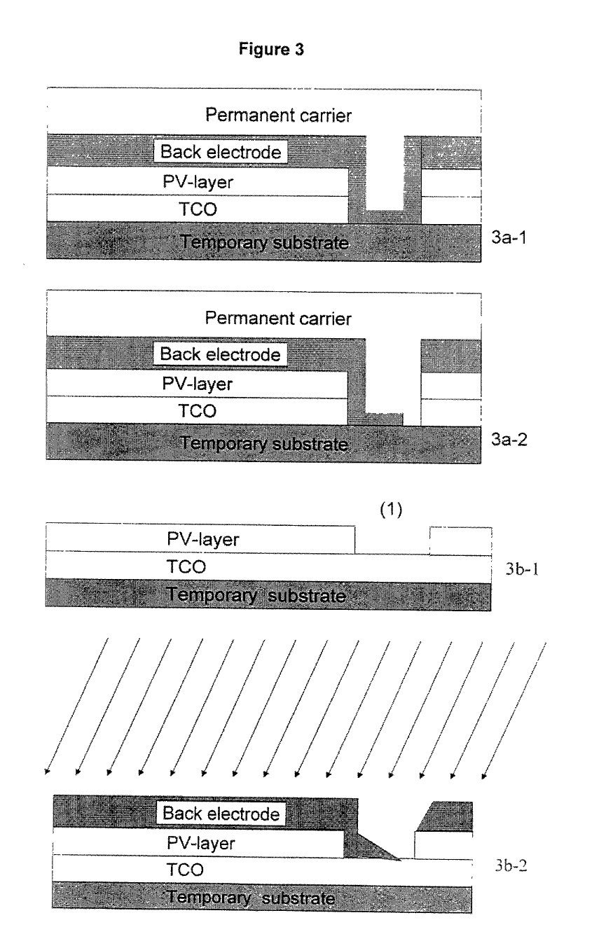

Groove 2 can be obtained in different ways. Two of these are illustrated in FIG. 3. The first way comprises first covering the entire surface of the thin film solar cell sheet with back electrode (FIG. 3a-1). Next, a groove (2) is provided in the back electrode in such a way that on one side of groove (2) the TCO and the back electrode are not interconnected. This produces the assembly illustrated in FIG. 3a-2. An alternative process, as illustrated in FIG. 3b-1, is to apply the back electrode by means of sputtering at an angle, such that one side of groove (1) and optionally a part of the bottom of groove (1) are covered with back electrode, while the other side of groove (1) and at least part of the bottom of groove (1) remain free of back electrode (FIG. 3b-2).

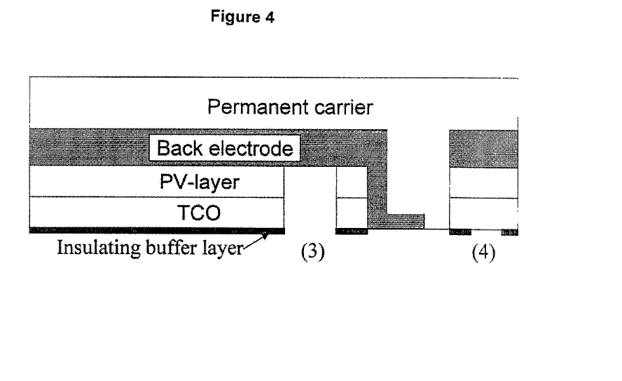

As will be elucidated in greater detail in the description of the temporary substrate, between the temporary substrate and the TCO there may be a transparent insulation spacer which, after removal of the temporary substrate, will be present on the TCO. If such is the case, it is necessary if a conductive contact is to be established between the TCO on one side of groove (1) and the back electrode on the opposite side of groove (1) in the embodiment illustrated in FIG. 2, to remove this insulation spacer from the TCO at the site where the conductive connection is provided. As is illustrated in FIG. 4, this can be done by providing a groove (4) through the insulation spacer down to the TCO. If so desired, groove (4) may be provided simultaneously with groove (3).

In yet another embodiment an electrode scribing step is eliminated. This process thus comprises the following steps:

a. providing a temporary substrate;

b. optionally providing a diffusion barrier layer;

c. applying a transparent conductive oxide (TCO);

d. applying a photovoltaic (PV) layer onto the TCO;

e. providing a groove (1) through the PV layer down to the TCO;

f. applying a back electrode onto the PV layer and in groove (1) in such a way that inside groove (1) the back electrode forms a contact with the front electrode, but back electrodes on both sides of the grove are electrically isolated from each other;

g. applying a non-conductive material in grooves (1) and (2a), optionally combined with or followed by the application of a permanent carrier;

h. removing the temporary substrate;

i. providing a groove (3) through the TCO and, if so desired, through the PV layer on the side of groove (1) opposite from groove (2a);

j. applying an insulating material in groove (3) and, if so desired, simultaneously or successively over the top of the thin film solar cell sheet.

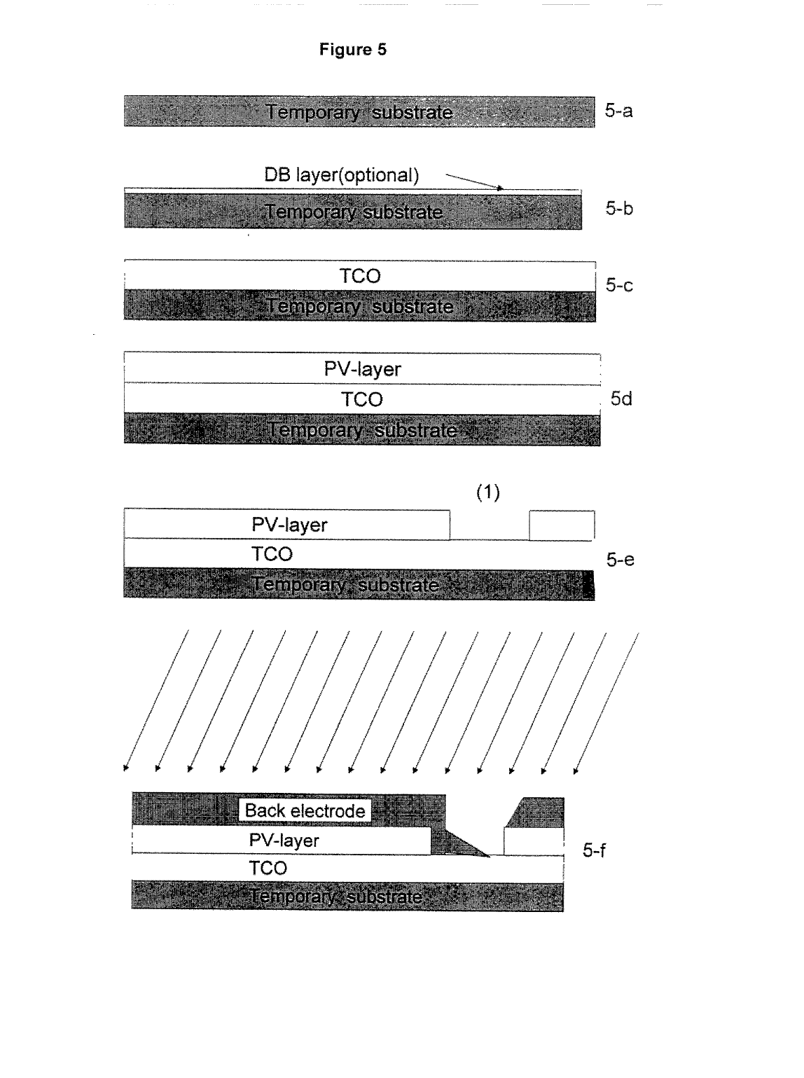

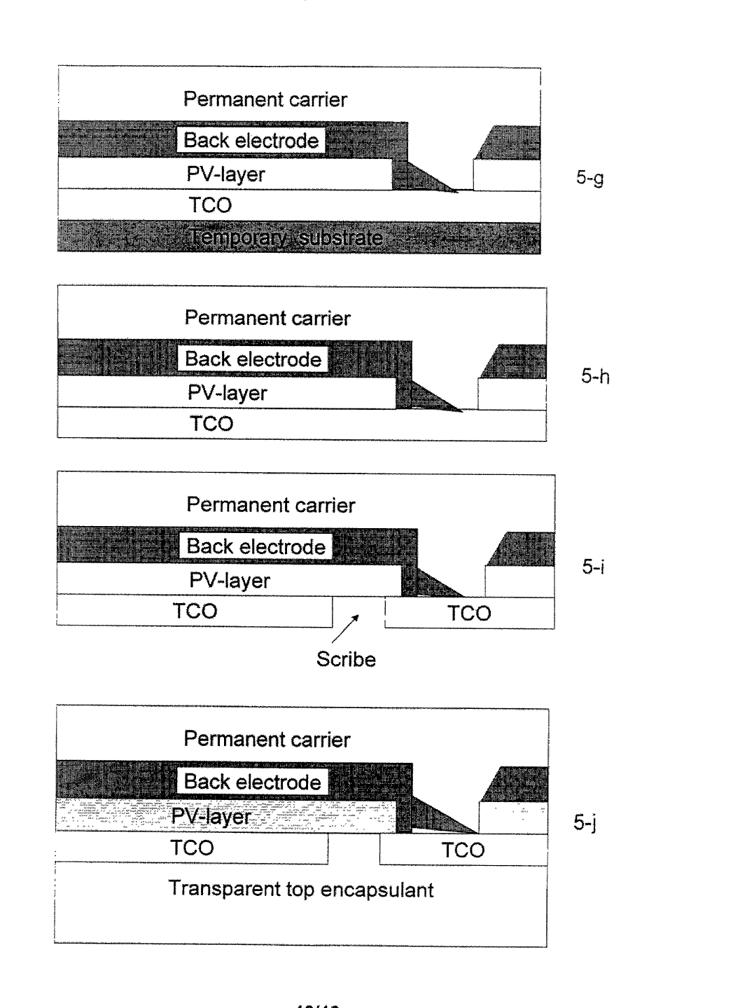

This process is further illustrated in FIGS. 5-a to 5-i corresponding to steps a-i as described above.

The grooves can be provided in a known manner with the aid of a laser. Etching techniques, or masking techniques may be used if so desired, but as a rule these are less preferred.

The width of the different grooves generally is determined by the following considerations. At the sites of grooves, the solar cell is unable to convert light into electricity. In view of this, the grooves have to be as narrow as possible. On the other hand, the grooves have to be wide enough to ensure that the desired effect, more particularly, the separation of the different layers, is in fact achieved. Examples of suitable groove widths are as follows.

In the embodiment illustrated in FIG. 1, groove (1) generally has a width of 2 to 200 μm, preferably 5 to 75 μm. Groove (2a) generally has a width of 2 to 200 μm, preferably 5 to 75 μm. Groove (3) generally has a width of 2 to 200 μm, preferably 5 to 75 μm.

In the embodiment illustrated in FIG. 2, groove (1) generally has a width of 2 to 200 μm, preferably 5 to 75 μm. Groove (2) generally has a width of 2 to 200 μm, preferably 5 to 75 μm. Groove (3) generally has a width of 2 to 200 μm, preferably 5 to 75 μm. Groove (4), illustrated in FIG. 4, when present generally has a width of 2 to 200 μm, preferably 5 to 75 μm.

The grooves generally are continuous grooves, since this guarantees good connection in series, the sole exception being groove (1) in the embodiment of Example (1). This groove serves to establish a connection between the back electrode of one cell and the TCO of another cell and may, if so desired, have a discontinuous form, i.e. in the form of holes or stripes. In the process according to the invention groove (3) can be provided in two different ways. Groove (3) can be provided through the TCO down to the PV layer or through the TCO and the PV layer down to the back electrode. For good order's sake it should be noted that the two alternatives can be applied in the embodiment illustrated in FIG. 1 as well as in the embodiment illustrated in FIGS. 2 and 5.

The invention also pertains to thin film solar cell sheets provided with solar cells connected in series, which can be obtained using the process according to the invention.

Thus the invention pertains to a thin film solar cell sheet provided with solar cells connected in series which comprises a carrier, a TCO, a PV layer, and a back electrode, with the cells being connected in series by means of a groove (1) in the PV layer comprising back electrode, and with short circuits being prevented by a groove (2a) in the back electrode down to the PV layer on one side of groove (1) and a groove (3) in the TCO and, optionally, the PV layer on the opposite side of groove (1), with grooves (2a) and (3) being filled with an insulating material. This is the thin film solar cell sheet which can be obtained using the method illustrated in FIG. 1.

The invention also pertains to a thin film solar cell sheet comprising a plurality of cells, wherein each cell comprises a TCO layer, which is superposed by a PV layer, which is superposed by a back electrode, and where in each of the cells the TCO layer and the PV layer possess a scribe, characterized in that the scribe of the TCO layer is completely filled with an electrically insulating encapsulant, and that the scribe of the PV layer is partly filled with the back electrode and partly filled with an electrically insulating permanent carrier, such that the back electrode of a cell is not in contact with the back electrode of an adjacent cell. Optionally, the scribe of the TCO layer may continue in the PV layer, and the scribe of the TCO layer and the continued scribe of the PV layer are then completely filled with an electrically insulating encapsulant. The invention further pertains to a thin film solar cell sheet provided with solar cells connected in series which comprises a carrier, a TCO, a PV layer, and a back electrode, with the connection in series being obtained by a groove (1) through the PV layer and the TCO, with one side of groove (1) being provided with back electrode and the opposite side and part of the bottom of groove (1) being free of back electrode and filled with an insulating material, with there being a conductive connection on the TCO side of the thin film between the back electrode on one side of groove (1) and the TCO on the opposite side of groove (1), and with there being a groove (3) through the TCO and, optionally, through the PV layer down to the back electrode outside groove (1) on the side of the groove where the TCO and the back electrode are interconnected, which groove (3) is filled with an insulating material. This is the thin film solar cell sheet which can be obtained using the process illustrated in FIG. 2.

The Temporary Substrate

The temporary substrate has to meet a number of requirements. It has to be sufficiently heat-resistant to withstand the conditions prevailing during the manufacture of the thin film solar cell sheet, more particularly, during the deposition of the TCO and the PV layer. It has to be strong enough to support the thin film solar cell sheet during its manufacture. It must be easily removable from the TCO layer without the latter being damaged in the process. Within the framework of these guidelines the skilled person will be able to select a suitable temporary substrate.

The temporary substrate may be a polymer. For example, it may be a “positive photoresist,” i.e., a light-sensitive material which can be extracted with a solvent under the influence of radiation, e.g., cross-linked polyimides. Since these materials are expensive, their use is not preferred. In this connection it is more attractive to employ polymers which can be removed by means of plasma etching, e.g., by O₂ plasma or, in the case of, say, polysiloxane polymers, SF₆ plasma. Although virtually all polymers are suitable for use in that case, polymers which are resistant to high temperatures (above 250° C. and more preferably above 400° C.) are preferred.

The temporary substrate used in the process according to the invention preferably is a thin film of a metal or metal alloy. The main reasons for this are that in general such thin films are resistant to high process temperatures, are slow to evaporate, and can be removed comparatively easily using known etching techniques. Another reason for selecting a thin film of metal, more particularly of aluminum or copper, is that in the end the thin film solar cell sheet has to be provided with edge electrodes which have to connect the thin film solar cell sheet to an apparatus or the electricity grid. Pieces of unremoved temporary substrate may be used to this end, as a result of which there is no need for separate provision of the edge electrodes.

Suitable metals include steel, aluminum, copper, iron, nickel, silver, zinc, molybdenum, and alloys or multi-layers thereof. For economic reasons among others it is preferred to employ Fe, Al, Cu, or alloys thereof. Given their performance (and taking into account the matter of cost) aluminum, iron made by electrodeposition, and copper made by electrodeposition are most preferred. Suitable etchants and techniques for removing metals are known, and while they differ per metal, the skilled person will be able to select the right ones. Preferred etchants include acids (Lewis as well as Brønstedt acids). Thus in the case of copper it is preferred to use FeCl₃, nitric acid or sulfuric acid. A suitable etchant for removing aluminum is, e.g., sodium hydroxide.

One specific reason why electrodeposited (galvanized) materials are preferred is because it is easy to provide them with a surface structure. This is important with regard to the functioning of the thin film solar cell sheet. For, to achieve efficient functioning of thin film solar cell sheets, it is desired that the incident light is scattered as fully as possible inside the cell. For that reason it is advisable to provide the surface of the solar cell and the other layers with a structure, for example a plurality of optical prisms. A key advantage of materials made by means of electrodeposition is that electrodeposition process makes it possible to provide the thin film with any structure desired. This can be done by providing the surface on which the electrodeposition is carried out, generally a roll, with a structure. When the thin film solar cell sheet is built up on a textured substrate, the substrate will act as a mould, imposing on its adjacent layer, and the subsequent layers, the negative image of said texture. The roll can be provided with a structure in a manner known as such, e.g., by means of laser scribing or a photolithographic process. Alternatively, a textured surface can be provided on the side of the substrate facing away from the roll. The texture on this side is affected not only by the surface texture of the roll and the material of which the roll is made, but also by process parameters such as the current density, the nature and the concentration of the electrolyte employed, and by any additives used. The skilled person will know how to adjust the different parameters in such a way as to attain a surface roughness of the order of 0.1 to 10 μm (perpendicular to the surface). In other words, by adjusting the texture of the temporary substrate, the texture of the TCO can be regulated to such an extent as will give it optimum surface morphology.

One particularly preferred embodiment of the above is a texture having a plurality of adjacent pyramids, thus having alternating protrusions and indentations. The comparative difference in height between the protrusions and the indentations preferably is of the order of 0.1 to 10 μm, more preferably 0.15 to 0.2 μm. It is preferred when the protrusions and indentations have a rounded shape, e.g., with an angle from base to hypotenuse of at most 40°. In this way possible defects in the PV layer are prevented. It will be clear that when protruding pyramids are present on the roll, their negative image will be imposed on the temporary substrate and thus on the other layers, so that these will have pyramid-shaped indentations.

With a view to possibly influencing the final texture of the thin film solar cell sheet, it is preferred to employ aluminum as temporary substrate. However, as aluminum may have the tendency to diffuse through the PV layer, it is preferred to provide the aluminum with a diffusion barrier layer, preferably a non-reducing diffusion barrier layer, e.g., an anti-corrosion layer, more particularly zinc oxide, or to select a TCO capable of preventing such diffusion, e.g., SiO_{X}, TiO₂, Al₂O₃, SnO₂, or ZnO. The anti-diffusion layers can be applied by means of electrodeposition via Physical Vapor Deposition (PVD) or via Chemical Vapor Deposition (CVD). The anti-diffusion layer generally is removed from the TCO together with the temporary substrate.

If so desired, the temporary substrate may be provided with a diffusion barrier layer, such as a transparent insulation spacer. Because of its transparency, this layer can be left on the TCO to serve as a protective layer for the TCO. The transparent insulation spacer preferably is made of glass. To keep the temporary substrate flexible, and for reasons of economy, the transparent insulation spacer preferably is very thin, e.g., having a thickness of 50-200 nm. One suitable method of applying such as layer is PECVD (Plasma Enhanced Chemical Vapor Deposition), e.g., of SiH₄ and N₂O (plasma oxide), while adding a suitable additive such as B₂H₆, to form a boron silicate glass of a favorable transparency. It is preferred to employ APCVD (Atmospheric Pressure Chemical Vapor Deposition) silicon oxide or mixed oxides of Si, Sn, Ti, preferably with small amounts (up to 30 wt. %) of B and/or P. For ease of removal, the temporary substrate preferably is as thin as possible. Of course, it has to be such that other layers can be deposited on it and it has to be able to hold these together, but this generally does not require it to be more than 500 μm (0.5 mm) thick. The thickness preferably is in the range of 1 to 200 μm (0.2 mm). Depending on the modulus of elasticity, the minimum thickness for a large number of materials will be 5 μm. Accordingly, a thickness of 5-150 μm, more particularly 10-100 μm, is preferred.

The TCO Layer

Examples of suitable transparent conductive oxides are indium tin oxide, zinc oxide, zinc oxide doped with aluminum, fluor, or boron, cadmium sulfide, cadmium oxide, tin oxide, and, most preferably, F-doped SnO₂. Said last-mentioned transparent electrode material is preferred, because it can form a desired crystalline surface with a columnar light scattering texture when applied at a temperature above 400° C., preferably in the range of 500 to 600° C. It is precisely in the case of this TCO material that the use of a temporary substrate capable of withstanding such a high temperature, and particularly the use of a textured metal substrate, is extremely attractive. In addition, the material is resistant to most etchants and has a better resistance to chemicals and better opto-electronic properties than the much-used indium tin oxide. Also, it is far less costly.

The TCO can be applied by means of methods known in the field, e.g., MOCVD (Metal Organic Chemical Vapor Deposition), sputtering, APCVD, PECVD, spray pyrolysis, evaporation (physical vapor deposition), electrodeposition, screen binding, sol-gel processes, etc. It is preferred to apply the TCO layer at a temperature above 250° C., preferably above 400° C., more preferably between 500 and 600° C., so that a TCO layer of the desired composition, properties and/or texture can be obtained.

The PV Layer

After application of the TCO layer the PV layer can be applied in an appropriate manner. It should be noted here that in the present description the term “PV layer” or “photovoltaic layer” comprises the entire system of layers needed to absorb the light and convert it into electricity. Suitable layer configurations are known, as are the methods for applying them. For the common general knowledge in this field reference may be had to Yukinoro Kuwano, “Photovoltaic Cells,” Ullmann's Encyclopedia, Vol.A20 (1992), 161 and “Solar Technology,” Ullmann's Encyclopedia, Vol.A24 (1993), 369.

Various thin film semiconductor materials can be used in manufacturing the PV layers. Examples are amorphous silicon (a-Si:H), microcrystalline silicon, polycrystalline amorphous silicon carbide (a-SiC) and a-SiC:H, amorphous silicon-germanium (a-SiGe), and a-SiGe:H. In addition, the PV layer in the thin film solar cell sheet according to the invention may comprise CIS (copper indium diselenide, CuInSe₂) PV cells, cadmium telluride cells, Cu(In,Ga)Se cells, ZnSe/CIS cells, ZnO/CIS cells and/or Mo/CIS/CdS/ZnO cells.

The PV layer preferably is an amorphous silicon layer when the TCO comprises a fluorine-doped tin oxide. In that case the PV layer will generally comprise a set, or a plurality of sets, of p-doped, intrinsic, and n-doped amorphous silicon layers, with the p-doped layers being situated on the side receiving the incident light.

In the a-Si-H embodiment the PV layer will at least comprise a p-doped amorphous silicon layer (Si-p), an intrinsic amorphous silicon layer (Si-i), and an n-doped amorphous silicon layer (Si-n). It may be that onto the first set of p-i-n layers a second and further p-i-n layers are applied. Also, a plurality of repetitive p-i-n (“pinpinpin” or “pinpinpinpin”) layers can be applied consecutively. By stacking a plurality of p-i-n layers, the voltage per cell is raised and the stability of the system is enhanced. Light-induced degradation, the so-called Staebler-Wronski effect, is diminished. Furthermore, the spectral response can be optimized by choosing different band-gap materials in the various layers, mainly the i-layers, and particularly within the i-layers. The overall thickness of the PV layer, more particularly of all the a-Si layers together, will generally be of the order of 100 to 2000 nm, more typically about 200 to 600 nm, and preferably about 300 to 500 nm.

The Back Electrode

The back electrode in the thin film solar cell sheet according to the invention preferably serves both as reflector and as electrode. Generally, the back electrode will have a thickness of about 50 to 500 nm, and it may comprise any suitable material having light reflecting properties, preferably aluminum, silver, or a combination of layers of both. These metal layers preferably are applied at a comparatively low temperature, e.g., below 250° C., by means of for instance (in vacuo) physical vapor deposition or sputtering. In the case of silver, it is preferred to first apply an adhesion promotor layer. TiO₂, CrO₂, and ZnO are examples of suitable materials for an adhesion promotor layer and have the advantage of also possessing reflecting properties when applied in a suitable thickness, e.g., of about 80 nm.

The Permanent Carrier

Although it is not essential to the process according to the invention, as a rule it is preferred to provide the thin film solar cell sheet with a permanent carrier. For, otherwise the thin film will be so thin that its fragility makes for difficult handling. When employed, the permanent carrier is applied over the back electrode. Suitable carrier layer materials include thin films of polymer, such as polyethylene terephthalate, poly(ethylene 2,6-naphthalene dicarboxylate), polycarbonate, polyvinyl chloride, or thin films of polymer having very good properties such as aramid or polyimide thin films, but also, for example, thin films of metal onto which an insulating (dielectric) surface layer has been applied, or compositions of epoxy and glass. Polymeric “co-extruded” thin films provided with a thermoplastic adhesive layer having a softening point below that of the carrier itself are preferred. If so desired, the co-extruded thin film may be provided with an anti-diffusion layer of, e.g., polyester (PET), copolyester or aluminum. The thickness of the carrier preferably is 75 μm to 10 mm. Preferred ranges are 100 μm to 6 mm and 150 μm to 300 μm. The flexural rigidity of the carrier, defined within the context of this description as the product of the modulus of elasticity E in N/mm² and the thickness t to the power of three in mm (E×t³) preferably is higher than 16×10⁻² Nmm and will generally be lower than 15×10⁶ Nmm.

The carrier may comprise a structure as required for its final use. Thus the carrier may comprise tiles, roofing sheets, car, and home trailer roofs, etc. In general, however, preference is given to the carrier being flexible. In that case a roll of thin film solar cell sheet is obtained which is ready for use and where sheets of the desired power and voltage can be cut off the roll. These can then be incorporated into (hybrid) roof elements or be applied onto tiles, roofing sheets, car and caravan roofs, etc., as desired.

If so desired, a top coat or surface layer may be provided on the TCO side of the solar cell to protect the TCO from outside influences. Generally, the surface layer will be a polymer sheet (with cavities if so desired) or a polymer film. The surface layer is required to have a high transmission and for instance comprises the following materials: amorphous (per)fluorinated polymers, polycarbonate, poly(methylmethacrylate), or any clear coating available, such as the ones used in the car industry. If so desired, an additional anti-reflection or anti-fouling layer may be provided. Alternatively, if so desired, the entire solar cell may be incorporated into such an encapsulant.

The Insulating Material

In the process according to the invention at various sites grooves are filled with an insulating material. This material, as the name implies, has to be insulating, as well as sufficiently flexible for application inside a groove. All cross-linked polymers are suitable for use in principle. Suitable materials are known to the skilled person. As will be clear to the skilled person, the material to be selected must be able to withstand the conditions under which the thin film solar cell sheet is to be applied, e.g., it has to be UV- and temperature-resistant. Examples of suitable materials are polyurethanes, epoxyamines, and acrylates.

The Conductive Connection

In the embodiment illustrated in FIG. 2 a conductive connection is established. Suitable materials to serve as conductive connections are coatings of polymers, e.g., the aforesaid ones, to which a conductive filler, such as particles of silver or flakes of nickel, is added. Such coatings are known to the skilled person. The coatings can be applied using well-known methods such as silk screening, ink-jet, or by means of spraying techniques.

Alternatively, the conductive connection can be established via sputtering, vacuum evaporation, or flame spraying of metals, e.g., aluminum. These technologies are known to the skilled person.

The invention will be elucidated below with reference to the following examples.

### EXAMPLE 1

This example illustrates the implementation of the process according to the invention as specified in the embodiment illustrated in FIG. 1.

The temporary substrate used is a thin film of aluminum (FIG. 1-a). Onto it a TCO layer of F-doped tin dioxide having a thickness of about 600-1,000 nm is applied by means of APCVD at a temperature of about 550° C. (FIG. 1-c). Next, PECVD is used to apply an amorphous silicon PV layer consisting of a player, an intrinsic layer, and an n-layer (FIG. 1-d). A groove (1) having a width of 25-50 μm is provided through the PV layer down to the TCO layer (FIG. 1e). Vacuum deposition is used to apply a back electrode of silver (FIG. 1-f), after which groove (2a) is provided in the back electrode with the aid of a laser (FIG. 1-g). A plastic carrier is then applied by means of lamination (FIG. 1-h). The (insulating) adhesive used in this process in addition fills groove (2a). The temporary aluminum substrate is then removed by etching (FIG. 1-i), after which a groove (3) is provided in the TCO layer with the aid of a laser (FIG. 1-j). Finally, an encapsulant is laminated onto the TCO (FIG. 1-k). This material fills groove (3) at the same time.

### EXAMPLE 2

This example illustrates the implementation of the process according to the invention as specified in the embodiment illustrated in FIG. 2. The temporary substrate used is a thin film of aluminum (FIG. 2-a). Onto it a transparent insulating SiOx-layer is applied (FIG. 2-b). Next, APCVD is used to apply a TCO layer of F-doped tin oxide (SnO₂) having a thickness of about 600 nm APCVD at a temperature of about 550° C. (FIG. 2-c). PECVD is then used to apply an amorphous silicon PV layer consisting of a p-layer, an intrinsic layer, and an n-layer (FIG. 2-d). A groove (1) having a width of 25-50 μm is provided through the PV layer and the TCO down to the thin film of aluminum (FIG. 2-e). Next, vacuum deposition is used to apply a back electrode of silver, after which groove (2) is provided with the aid of a laser (FIG. 2-f. Grooves (1) and (2) are filled with an insulating material, after which a plastic carrier is applied (FIG. 2-g). The temporary aluminum substrate is removed by etching (FIG. 2-h), followed by grooves (3) and (4) being provided with the aid of a laser, with groove (3) cutting through the TCO and the PV layer down to the back electrode and groove (4) only cutting through the insulating layer down to the TCO (FIG. 4). A printing technique is used to establish a conductive connection consisting of a conductive ink. This connection connects the TCO via groove (4) to the back electrode on the opposite side of groove (1) (FIG. 2-j). Next, a surface layer of an insulating material is applied. This also serves to fill groove (3) (FIG. 2-k).

1. A process for manufacturing a thin film solar cell sheet provided with a plurality of solar cells connected in series which comprises the following steps:
a. providing a temporary substrate;
b. optionally providing a diffusion barrier layer;
c. applying a transparent conductive oxide (TCO);
d. applying a photovoltaic (PV) layer onto the TCO;
e. providing a groove (1) through the PV layer and, if so desired, through the TCO;
f. applying a back electrode onto the PV layer and in groove (1) and, when groove (1) has been provided through the TCO, if necessary providing a groove (2) in the back electrode inside groove (1) down to the temporary substrate in such a way that on one side of groove (2) the TCO and the back electrode are not interconnected, and when groove (1) has not been provided through the TCO, providing a groove (2a) through the back electrode down to the PV layer next to groove (1);
g. applying a non-conductive material in grooves (1) and (2) or (2a), optionally combined with or followed by the application of a permanent substrate;
h. removing the temporary substrate;
i. providing a groove (3) from the TCO side through the TCO and, if so desired, through the PV layer outside groove (1) on the side of groove (1) opposite from groove (2) or (2a);
j. when groove (1) has been provided through the TCO, establishing a conductive connection between the TCO on the side of groove (2) where the TCO and the back electrode are not interconnected and the back electrode on the opposite side of groove (2);
k. applying an insulating material in groove (3) and, if so desired, simultaneously or successively over the top of the thin film solar cell sheet.

2. The process according to claim 1 wherein in step e the groove is provided through the PV layer down to the TCO and in step f the groove (2a) is provided through the back electrode down to or, if so desired, through the PV layer, but not completely through the TCO layer, next to groove (1).

3. The process according to claim 2 wherein steps a-k are replaced by the following steps a-j:
a. providing a temporary substrate;
b. optionally providing a diffusion barrier layer;
c. applying a transparent conductive oxide (TCO);
d. applying a photovoltaic (PV) layer onto the TCO;
e. providing a groove (1) through the PV layer down to the TCO;
f. applying a back electrode onto the PV layer and in groove (1) in such a way that inside groove (1) the back electrode forms a contact with the front electrode, but back electrodes on both sides of the groove are electrically insulated from each other;
g. applying a non-conductive material in grooves (1) and (2a), optionally combined with or followed by the application of a permanent carrier;
h. removing the temporary substrate;
i. providing a groove (3) through the TCO and, if so desired, through the PV layer on the side of groove (1) opposite from groove (2a);
j. applying an insulating material in groove (3) and, if so desired;
simultaneously or successively over the top of the thin film solar cell sheet.

4. The process according to claim 1 wherein in step e groove (1) is not provided through the TCO and in step f in addition to groove (1) a groove (2a) is provided through the back electrode down to the PV layer.

5. The process according to claim 1 wherein in step e groove (1) is provided through the TCO down to the back electrode, in step f, if necessary, a groove (2) is provided in the back electrode inside groove (1) down to the temporary substrate in such a way that on one side of groove (2) the TCO and the back electrode are not interconnected, and in step j a conductive connection is established between the TCO on the side of groove (2) where the TCO and the back electrode are not interconnected and the back electrode on the opposite side of groove (2).

6. The process according to claim 5 wherein the back electrode is provided by means of sputtering at an angle, in such a way that one side of groove (1) and optionally part of the bottom of groove (1) are covered with back electrode, while the opposite side of groove (1) and at least part of the bottom of groove (1) remain free of back electrode.

7. The process according to claim 5 wherein an insulating layer is present between the temporary substrate and the TCO which is left on the TCO after removal of the temporary substrate, which insulating layer is removed in a groove (4) provided on the side of groove (1) opposite from groove (3).

8. The process according to claim 7 wherein groove (3) and groove (4) are provided simultaneously.

9. A thin film solar cell sheet comprising a plurality of cells, wherein each cell comprises a TCO layer, which is superposed by a PV layer, which is superposed by a back electrode, and where in each of the cells the TCO layer and the PV layer possess a scribe, characterized in that the scribe of the TCO layer is completely filled with an electrically insulating encapsulant, and that the scribe of the PV layer is partly filled with the back electrode and partly filled with an electrically insulating permanent carrier, such that the back electrode of a cell is not in contact with the back electrode of an adjacent cell.

10. The thin solar cell of claim 9 wherein the scribe of the TCO layer continues in the PV layer, and the scribe of the TCO layer and the continued scribe of the PV layer are completely filled with an electrically insulating encapsulant.

11. A thin film solar cell sheet which can be obtained using the process according to any one of claims 1-8.

12. The thin film solar cell sheet of claim 11 provided with solar cells connected in series which comprises a carrier, a TCO, a PV layer, and a back electrode, comprising a groove (1) in the PV layer which comprises back electrode, a groove (2a) in the back electrode down to the PV layer on one side of groove (1), and a groove (3) through the TCO and optionally through the PV layer on the opposite side of groove (1), with grooves (2a) and (3) being filled with an insulating material.

13. The thin film solar cell sheet of claim 11 provided with solar cells connected in series which comprises a carrier, a TCO, a PV layer, and a back electrode, wherein a connection in series is obtained by a groove (1) through the PV layer and the TCO, wherein one side of groove (1) is provided with back electrode and the opposite side and part of the bottom of groove (1) are free of back electrode and filled with an insulating material, wherein on the TCO side of the thin film there is a conductive connection between the back electrode on one side of groove (1) and the TCO on the opposite side of groove (1), and wherein outside groove (1) on the side of the groove where the TCO and the back electrode are interconnected there is a groove (3) through the TCO and optionally through the PV layer down to the back electrode, which groove (3) is filled with an insulating material.
